(19) United States
(12) Patent Application Publication
(10) Pub. No.: US 2025/0293521 A1
(43) Pub. Date: Sep. 18, 2025

(54) ELECTRICAL CONTROL SYSTEM AND METHOD

(71) Applicant: Purdue Research Foundation, West Lafayette, IN (US)

(72) Inventors: Kevin James Kircher, Lafayette, IN (US); Elias Nikolaos Pergantis, West Lafayette, IN (US); Levi Darian Reyes Premer, West Lafayette, IN (US); Davide Ziviani, West Lafayette, IN (US)

(21) Appl. No.: 19/079,543

(22) Filed: Mar. 14, 2025

Related U.S. Application Data
(60) Provisional application No. 63/566,019, filed on Mar. 15, 2024.

(51) Int. Cl. H02J 3/00; G01R 11/54

(52) U.S. Cl. CPC H02J 3/0075; G01R 11/54; H02J 3/003; H02J 2310/14; H02J 2310/60; H02J 2310/62

(57) ABSTRACT

The control system includes an electrical meter and a processor. The electrical meter may be configured to monitor the current draw of the electrical system. The processor is communicatively coupled to the electrical meter. The processor also includes an optimization algorithm. The processor may accept input information about the electrical system, such as an electrical capacity of the electrical system, a performance limit of the electrical system, and building electrical usage characteristics. The processor performs the optimization algorithm and outputs a control protocol of a first appliance and a second appliance to maintain the current draw below the predetermined amperage.

### CROSS REFERENCE TO RELATED APPLICATIONS

This application claims the benefit of U.S. Provisional Application No. 63/566,019 filed Mar. 15, 2024, the entirety of which is hereby incorporated by reference.

### FIELD

The disclosure generally relates to control systems and, more particularly, to control systems for electrical configurations.

### INTRODUCTION

This section provides background information related to the present disclosure which is not necessarily prior art.

The U.S. Department of Energy and other federal agencies are set to invest substantial sums of time and expense to improve the electrical grid due to increasing demands. Likewise, millions of buildings and homes throughout the United States are expected to require upgrades to their electrical infrastructure with growing penetration of electrical systems such as heat pumps, ovens, water heaters, etc. These upgrades are expected to be costly for both homeowners and utility companies.

Generally, buildings with older electrical panels may be insufficient for modern electrical demands. For instance, many older buildings have panels limited to 50, 75, or 100 amps. These older buildings may experience certain risks when utilizing larger modern electric devices such as water heaters and space heaters. Specifically, provided as a non-limiting example, colder climates are already experiencing limitations to heating alternatives to gas-fired systems. For instance, heat pumps and backup heating elements may require panel upgrades due to the potential of overloading the building electrical infrastructure when utilized in combination with other electrically demanding appliances.

Accordingly, there is a continuing need for a control system that may regulate the peak electrical demand between a plurality of appliances and/or electrical systems. Desirably, the control system may be easily implemented in existing electrical infrastructures without requiring an electrical panel upgrade.

### SUMMARY

In concordance with the instant disclosure, a control system that may regulate the peak electrical demand between a plurality of appliances and/or electrical systems, has surprisingly been discovered. Desirably, the control system may be easily implemented in existing electrical infrastructures without requiring an electrical panel upgrade.

The control system is configured to maintain a current draw of an electrical system below a predetermined amperage. The control system includes an electrical meter and a processor. In a specific example, the control system may include a first control device and a second control device. The electrical meter may be configured to monitor the current draw of the electrical system. The processor may be communicatively coupled to the electrical meter. The processor may also include an optimization algorithm. The first control device may be coupled to a first appliance and communicatively coupled to the processor. The second control device may be coupled to a second appliance and communicatively coupled to the processor. In another non-limiting example, the first appliance and/or the second appliance may be communicatively coupled to the processor via an application program interface. This may allow for the first appliance and/or the second appliance to directly communicate and receive instructions from the processor. It is contemplated that the control system may additionally monitor and control any number of subsequent appliances. The processor may accept input information about the electrical system, such as an electrical capacity of the electrical system, a performance limit of the electrical system, thermodynamic characteristics of the electrical system, and building/occupant usage characteristics. The processor may perform the optimization algorithm and output a control protocol of the first appliance via the first control device and the second appliance via the second control device to maintain the current draw below the predetermined amperage. In a specific example, the control protocol may include selectively engaging and/or disengaging the first appliance and/or the second appliance. In another specific example, the control protocol may include adjusting a setpoint of the first appliance and/or the second appliance.

In certain circumstances, the control system may be used in various ways. For instance, the control system may be used according to a method. The method may include a step of providing an electrical meter, a processor, a first control device, and a second control device. The electrical meter may be configured to monitor the current draw of the electrical system. The processor may be communicatively coupled to the electrical meter. The processor may include an optimization algorithm. The first control device may be coupled to a first appliance and communicatively coupled to the processor. The second control device may be coupled to a second appliance and communicatively coupled to the processor. Next, the method may include a step of accepting input information of the electrical system via the processor. Then, the method may include a step of performing the optimization algorithm. Afterwards, the method may include a step of outputting a control protocol. Then, the method may include a step of controlling the current draw of the first appliance via the first control device and the second appliance via the second control device below the predetermined amperage. Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations and are not intended to limit the scope of the present disclosure.

FIG. 1 is a schematic diagram of the control system, according to one embodiment of the present disclosure;

FIG. 2 is a schematic diagram of the control system, further depicting the implementation of the control system into a residential electrical system where the first appliance is a heat pump thermostat and the second appliance is a water heater thermostat, according to one embodiment of the present disclosure;

FIG. 3A is dot plot illustrating the energy usage of a house during a baseline period without the use of the optimization algorithm, according to one embodiment of the present disclosure;

FIG. 3B is dot plot illustrating the energy usage of same house, as referred to in FIG. 3B, with the use of the control system with the optimization algorithm, further depicting a lower overall usage of energy when the control system with the optimization algorithm is engaged, according to one embodiment of the present disclosure;

FIG. 4 is a flowchart of a method for using the control system, according to one embodiment of the present disclosure; and

FIG. 5 is a schematic diagram of the control system, further depicting the control system having a communication interface, an input interface, a user interface, and a system circuitry, wherein the system circuitry may include a processor and a memory, according to one embodiment of the present disclosure.

### DETAILED DESCRIPTION

The following description of technology is merely exemplary in nature of the subject matter, manufacture, and use of one or more inventions, and is not intended to limit the scope, application, or uses of any specific invention claimed in this application or in such other applications as may be filed claiming priority to this application, or patents issuing therefrom. Regarding methods disclosed, the order of the steps presented is exemplary in nature, and thus, the order of the steps can be different in various embodiments, including where certain steps can be simultaneously performed. “A” and “an” as used herein indicate “at least one” of the item is present; a plurality of such items may be present, when possible. Except where otherwise expressly indicated, all numerical quantities in this description are to be understood as modified by the word “about” and all geometric and spatial descriptors are to be understood as modified by the word “substantially” in describing the broadest scope of the technology. “About” when applied to numerical values indicates that the calculation or the measurement allows some slight imprecision in the value (with some approach to exactness in the value; approximately or reasonably close to the value; nearly). If, for some reason, the imprecision provided by “about” and/or “substantially” is not otherwise understood in the art with this ordinary meaning, then “about” and/or “substantially” as used herein indicates at least variations that may arise from ordinary methods of measuring or using such parameters.

Although the open-ended term “comprising,” as a synonym of non-restrictive terms such as including, containing, or having, is used herein to describe and claim embodiments of the present technology, embodiments may alternatively be described using more limiting terms such as “consisting of” or “consisting essentially of.” Thus, for any given embodiment reciting materials, components, or process steps, the present technology also specifically includes embodiments consisting of, or consisting essentially of, such materials, components, or process steps excluding additional materials, components or processes (for consisting of) and excluding additional materials, components or processes affecting the significant properties of the embodiment (for consisting essentially of), even though such additional materials, components or processes are not explicitly recited in this application. For example, recitation of a composition or process reciting elements A, B and C specifically envisions embodiments consisting of, and consisting essentially of, A, B and C, excluding an element D that may be recited in the art, even though element D is not explicitly described as being excluded herein.

As referred to herein, disclosures of ranges are, unless specified otherwise, inclusive of endpoints and include all distinct values and further divided ranges within the entire range. Thus, for example, a range of “from A to B” or “from about A to about B” is inclusive of A and of B. Disclosure of values and ranges of values for specific parameters (such as amounts, weight percentages, etc.) are not exclusive of other values and ranges of values useful herein. It is envisioned that two or more specific exemplified values for a given parameter may define endpoints for a range of values that may be claimed for the parameter. For example, if Parameter X is exemplified herein to have value A and also exemplified to have value Z, it is envisioned that Parameter X may have a range of values from about A to about Z. Similarly, it is envisioned that disclosure of two or more ranges of values for a parameter (whether such ranges are nested, overlapping, or distinct) subsume all possible combinations of ranges for the value that might be claimed using endpoints of the disclosed ranges. For example, if Parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, 3-9, and so on.

When an element or layer is referred to as being “on,” “engaged to,” “connected to,” or “coupled to” another element or layer, it may be directly on, engaged, connected, or coupled to the other element or layer, or intervening elements or layers may be present. In contrast, when an element is referred to as being “directly on,” “directly engaged to,” “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one clement, component, region, layer or section from another region, layer, or section. Terms such as “first,” “second,” and other numerical terms when used herein do not imply a sequence or order unless clearly indicated by the context. Thus, a first element, component, region, layer, or section discussed below could be termed a second element, component, region, layer, or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the FIG. is turned over, elements described as “below”, or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

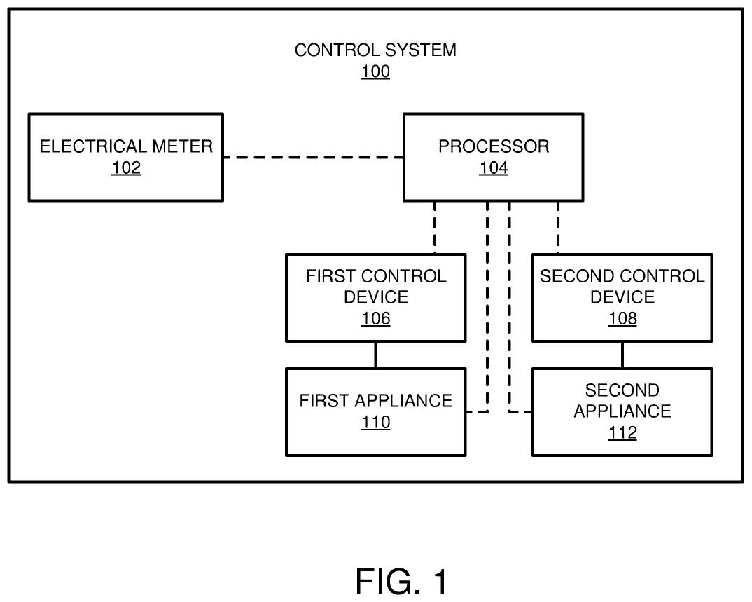

The control system 100 is configured to maintain a current draw of an electrical system below a predetermined amperage. Provided as a non-limiting example, the predetermined amperage may be around four hundred amps or less. As shown in FIG. 1, the control system 100 includes an electrical meter 102, a processor 104. In a specific example, the control system 100 may include a first control device 106, and a second control device 108. The electrical meter 102 may be configured to monitor the current draw of the electrical system. The processor 104 may be communicatively coupled to the electrical meter 102. The processor 104 may also include an optimization algorithm. The first control device 106 may be coupled to a first appliance 110 and communicatively coupled to the processor 104. The second control device 108 may be coupled to a second appliance 112 and communicatively coupled to the processor 104. In another non-limiting example, the first appliance 110 and/or the second appliance 112 may be communicatively coupled to the processor 104 via an application program interface. This may allow for the first appliance 110 and/or the second appliance 112 to directly communicate and receive instructions from the processor 104. The processor 104 may accept input information about the electrical system, such as an electrical capacity of the electrical system, a performance limit of the electrical system, and building electrical usage characteristics. The input information may be manually entered by a user. The input information may also be entered automatically upon connecting the electrical system to the processor 104. The processor 104 may perform the optimization algorithm and output a control protocol of the first appliance 110 via the first control device 106 and the second appliance 112 via the second control device 108 to maintain the current draw below the predetermined amperage. In a specific example, the control protocol may include selectively engaging and/or disengaging the first appliance 110 and/or the second appliance 112. In another specific example, the control protocol may include adjusting a setpoint of the first appliance 110 and/or the second appliance 112.

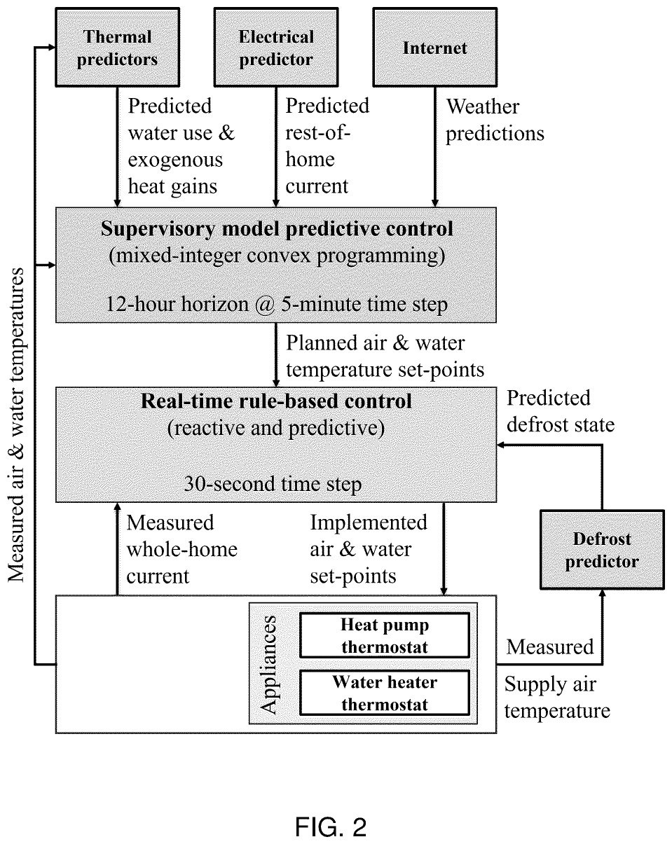

As illustrated in FIG. 2, the first appliance 110 and the second appliance 112 may include most, if not all, electrical appliances drawing electrical energy from the building's electrical infrastructure. It is also contemplated that the control system 100 may control any number of appliances. For instance, the control system 100 may control a third appliance, or any number of appliances, independently or simultaneously with the first applicant 110 and the second appliance 112. Provided as non-limiting examples, the first appliance 110 and/or the second appliance 112 may include a heat pump, an air conditioner, a water heater (electric, heat pump, hybrid), an electrical vehicle charger, a dishwasher, a stove, a dryer, and a washer. The control system 100 may interface with an HVAC system through relays, smart breakers, wireless communication (APIs or a standardized communication protocol), and/or direct integration with a thermostat. The control system 100 may interface with a water heater via relays, smart breakers, wireless communication via (APIs or a standardized communication protocol), and/or direct communication ports on the unit. The control system 100 may also interface with an EV charger using active power electronics, wireless or hardwired communication protocols (standardized communication protocols or APIs), and/or smart breakers. One skilled in the art may select other suitable appliances to control to maintain the electrical draw of the building below the predetermined amperage. It is also contemplated that the control system 100 may be implemented in various buildings beyond single family homes. For instance, provided as non-limiting examples, the control system 100 may be utilized in a multi-family home, an apartment complex, a commercial building, or a plurality of buildings that may use a common electrical infrastructure and/or utility bucket transformer.

The first appliance 110 and the second appliance 112, and any subsequent appliance, may communicate with processor 104 in various ways. For instance, as previously discussed, the first control device 106 and the second control device 108 may communicatively couple the processor 104 to each of the first appliance 110 and the second appliance 112, respectively. Provided as a non-limiting example, the first control device 106 and/or the second control device 108 may be provided as a smart plug. The smart plug may also be disposed as an interface between the electrical system of the building and each appliance. The first control device 106 and/or the second control device 108 may include a switch that permits the selective actuation or disengagement of the respective appliance from the electrical system of the building. For example, the switch of the first control device 106 may switch off a relay based on instructions from the processor 104 to selectively power off the first appliance 110, such as a dryer, while electricity is required for another appliance in the building. Alternatively, the first appliance 110 and/or the second appliance 112 may directly communicate with the processor 104. In other words, the processor 104 may include a network connection with the appliance itself. For instance, the first appliance 110 and/or second appliance 112 may include an application program interface, which may allow for the respective appliance to be controlled remotely. In a specific example, the application program interface may also selectively engage and/or disengage the appliance based on instructions from the processor 104. In another specific example, the application program interface may change settings on the appliance. For instance, the application program interface may selectively lower the set-point on a connected thermostat. One skilled in the art may select other suitable ways for processor 104 to communicate with each appliance, within the scope of the present disclosure.

The control system 100 may be used in various ways. In a specific example, the optimization algorithm may include a reactive protocol by accepting a real-time electrical draw from the electrical meter 102 and adjust the control protocol accordingly. For example, if the first appliance 110 is a heat pump and undergoes a defrost condition, the increased electrical draw may be detected in real time by the processor 104. The processor 104 may reactively perform the optimization algorithm to output an update to the control protocol which may adjust the operation of the first device and/or the second device. In another specific example, the processor 104 may include a predictive protocol by predicting a future current draw and preemptively perform the optimization algorithm to adjust the control protocol to maintain the current draw below the predetermined amperage. For instance, the processor 104 may include a machine learning module that may predict behavior based on routine electrical demands. For example, where the first appliance 110 and the second appliance 112 are routinely engaged during overlapping periods, data from the machine learning module be utilized by the processor 104 to adjust the control protocol to militate against the current draw from exceeding the predetermined amperage. More specifically, the control protocol may be adjusted to engage the first appliance 110 and the second appliance 112 during non-overlapping periods. Alternatively, the control protocol may reduce a setpoint of the first appliance 110 and/or the second appliance 112. One skilled in the art may select other suitable ways for using the control system 100, within the scope of the present disclosure.

With continued reference to using the control system 100, the predictive protocol may be the primary operating methodology. The predictive protocol may otherwise be known as the slow layer, as shown in FIG. 2. The predictive protocol may utilize a variety of resources to estimate future current draw amounts. For instance, the predictive protocol may utilize data from the machine learning module for typical building usage, weather service reports to estimate heating and cooling demands, and grid signals such as emissions and demand response. When an unanticipated current draw is detected, the reactive protocol may be temporarily engaged as a secondary operating methodology. The reactive protocol may otherwise be known as the fast layer, as shown in FIG. 2. In certain circumstances, the reactive protocol may be engaged until the current draw realigns with expected current draw amounts. The control system 100 may then revert back to the predictive protocol. In another specific example, where the unanticipated current draw is detected, the reactive protocol may be engaged for a set timeframe before reverting to the predictive protocol. In yet another specific, non-limiting example, the reactive protocol and the predictive protocol may operate under a master-slave architecture. For instance, where a user tries to start an appliance, the control system 100 may utilize the reactive protocol to determine if there is enough current capacity to engage the appliance without exceeding the predetermined amperage. If there is enough current capacity, the control system 100 may permit the appliance to start. However, if there is not enough current capacity, the control system 100 will not allow the appliance to start until enough current capacity becomes available. One skilled in the art may select other suitable ways for utilizing the control system 100, within the scope of the present disclosure.

In certain circumstances, the control system 100 may provide a control protocol without an optimization component. For instance, the control protocol may instead utilize a purely logic-based protocol and/or a heuristic protocol (simple if-else logic). Advantageously, the non-optimized protocols may be more easily implemented on a variety of appliances. However, the non-optimized protocols may not provide as enhanced performance and energy efficiency as the optimized protocol. One skilled in the art may select other suitable designs for providing the control protocol, within the scope of the present disclosure.

The first control device 106 and the second control device 108 may be provided in various ways. For instance, the first control device 106 and the second control device 108 may be hardwired onto the first appliance 110 and/or the second appliance 112, respectively. Alternatively, the first control device 106 and the second control device 108 may be provided as an intermediary between the first appliance 110/second appliance 112, respectively, and the electrical infrastructure of the building. In a specific example, the first control device 106 and the second control device 108 may be provided as a smart plug that may be inserted into an outlet of the electrical infrastructure and may also accept the electrical plug of the first appliance 110/second appliance 112, respectively. In another specific example, the first control device 106 and the second control device 108 may be communicatively coupled to the processor 104 with a wireless connection, such an internet connection, Wi-Fi network, and/or Bluetooth. The first control device 106 and the second control device 108 may include communication switches and/or relays that may switch on/off, delay, or early-start operation. A skilled artisan may select other suitable ways for providing the first control device 106 and the second control device 108, within the scope of the present disclosure.

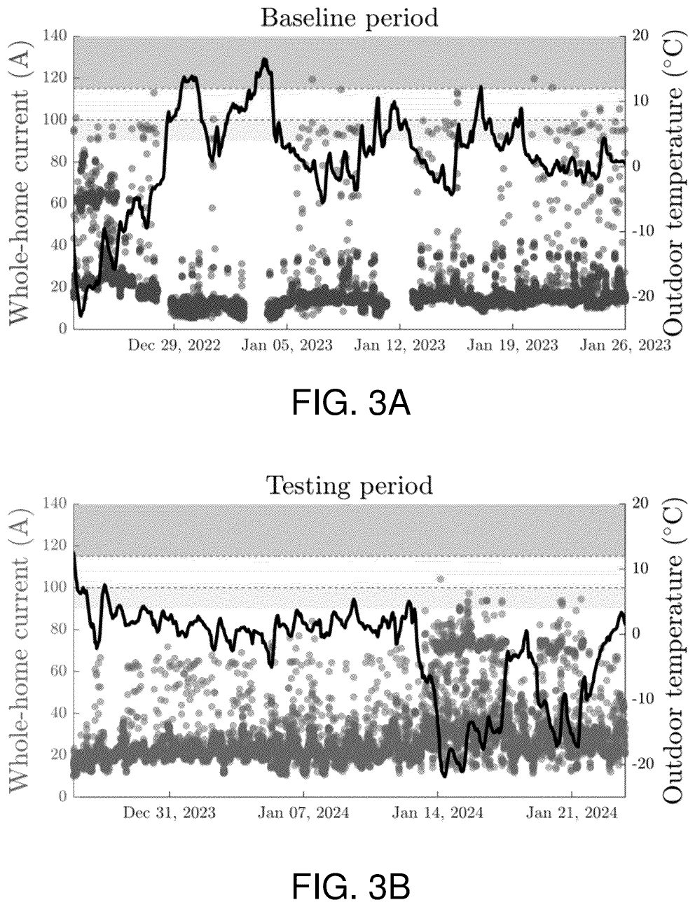

The processor 104 may be provided in various ways. For instance, the processor 104 may include a memory 116. The memory 116 may include a predetermined set of instructions for carrying out actions of the control protocol and/or the optimization algorithm. As shown in FIG. 3, the processor 104 may include a cloud-based system that wirelessly communicates with the electrical meter 102, the first control device 106, and the second control device 108. In a specific example, the processor 104 may utilize IoT communication with secure user credentials for each appliance. In another specific example, the processor 104 may communicate to the first appliance 110, such as a thermostat, through local area communication protocols, Modbus, Canbus, Zigbee, Bluetooth, etc. One skilled in the art may select other suitable ways for providing the processor 104, within the scope of the present disclosure.

In certain circumstances, the optimization algorithm may be provided in many ways. The optimization algorithm may include different inputs such as the usage of the building including, but not limited to occupancy, water usage, insulation, thermostat response time, etc. Using these inputs, a plurality of scenarios may be analyzed to determine how to most effectively and efficiently maintain the usage of the building while militating against the current draw from exceeding the predetermined amperage. As a non-limiting example, the optimization algorithm may include various objectives, states, expressions, and constraints such as those provided below:

$$Objectives : {min}_{T , Q} J = {π}_{I} {max}_{S} ( {max}_{k} ( max ( ( {I}_{HP} + {I}_{EWH} + {I}_{home} - {I}_{safety} ) , 0 ) ) ) + \frac{1}{S} {\sum }_{n = 1}^{S} ( {\sum }_{k = 1}^{K} Δ l {π}_{c} {P}_{k} + {π}_{t} \vert {\tilde{T}}_{pref , k} - {\tilde{T}}_{k} \vert + {π}_{w} \vert {\tilde{T}}_{w , pref , k} - {\tilde{T}}_{w , k} \vert )$$

$$\begin{matrix}States ( air ) : & {T}_{k + 1} = α {T}_{k} + ( 1 - α ) [ {θ}_{k} + R ( {\dot{Q}}_{c , k} + {\hat{\dot{Q}}}_{c , k} + {z}_{max} \frac{{P}_{AUX , max}}{4} ) ] \\ & {T}_{k + 1} = {bT}_{k} + ( 1 - b ) ( {\tilde{T}}_{k} - 0.5 γ )\end{matrix}$$

$$States ( water ) : {T}_{w , k + 1} = {α}_{w} {T}_{w , k} + ( 1 - {α}_{w} ) [ {T}_{air} + {R}_{w} ( {\hat{\dot{Q}}}_{draw , k} + {z}_{KWH} {P}_{EWH} ) ]$$

$$Initial states : {T}_{0} = {T}_{initial , building} ; {T}_{w , 0} = {T}_{initial , WH}$$

$$Expressions : {I}_{HP} = \frac{{\dot{Q}}_{c}}{{V}_{HP} {PF}_{HP} COP} + \frac{{P}_{AUX}}{{V}_{AUX} {PF}_{AUX}} ; {I}_{EWH} = {z}_{EWH} \frac{{P}_{EWH}}{{V}_{EWH}}$$

$$\begin{matrix}Inequality Constraints : & {T}_{w , min} \leq {T}_{w} \leq {T}_{w , max} \\ & {T}_{min} \leq T \leq {T}_{max} \\ & {z}_{HP} COP {P}_{min} \leq {\dot{Q}}_{c} \leq {z}_{HP} COP {P}_{max}\end{matrix}$$

$$\begin{matrix}Equality Constraints : & {\tilde{T}}_{i , 1} = {\tilde{T}}_{j , 1} ; {\tilde{T}}_{w , i , 1} = {\tilde{T}}_{w , j , 1} for i , j ∈ ( 1 , S ) \\ & Integer {z}_{nux} = 0 ⋃ ( 2 , 4 ) ; \\ & Binary {z}_{EWH} = 0 , 1 ; {z}_{HP} = 0 , 1\end{matrix}$$

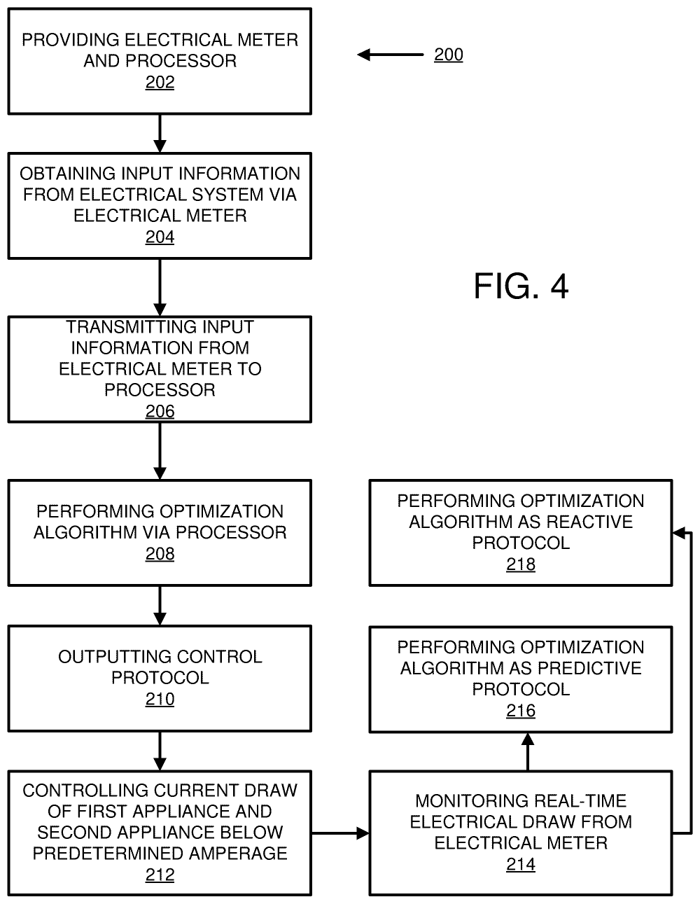

In certain circumstances, the control system 100 may be used in various ways. For instance, the control system 100 may be used according to a method 200. As shown in FIG. 4, the method may include a step 202 of providing an electrical meter 102, a processor 104, a first control device 106, a second control device 108. The electrical meter 102 may be configured to monitor the current draw of the electrical system. The processor 104 may be communicatively coupled to the electrical meter 102. The processor 104 may include an optimization algorithm. The first control device 106 may be coupled to a first appliance 110 and communicatively coupled to the processor 104. The second control device 108 may be coupled to a second appliance 112 and communicatively coupled to the processor 104. Next, the method 200 may include a step 204 of accepting input information of the electrical system via the processor 104. Then, the method 200 may include a step 206 of performing the optimization algorithm. Afterwards, the method 200 may include a step 208 of outputting a control protocol. Then, the method 200 may include a step 210 of controlling the current draw of the first appliance 110 via the first control device 106 and the second appliance 112 via the second control device 108 below the predetermined amperage. A skilled artisan may select other suitable steps for using the control system 100, within the scope of the present disclosure.

In certain circumstances, the method 200 may include ways monitor and provide adjustments during use. For instance, a real-time electrical draw from the electrical meter 102 may be continuously monitored. The optimization algorithm may be performed as a predictive protocol by predicting a future current draw event and performing the optimization algorithm to preemptively adjust the control protocol to maintain the current draw below the predetermined amperage during the future current draw event. The optimization algorithm may also be performed as a reactive protocol to output an update to the control protocol which may adjust the operation of the first device 106 and/or the second device 108. The operation of the first device 106 and/or the second device 108 may include a variety of controls, such as adjusting a setpoint of a heat pump or disabling an auxiliary heat source. In a specific example, the reactive protocol may be utilized for a predetermined period of time before reverting to the predictive protocol. In a more specific example, the control protocol may disengage the first appliance 106 and/or the second appliance 108 until the processor 104 determines there is enough current capacity to engage the first appliance 106 and/or the second appliance 108 without exceeding the predetermined amperage. A skilled artisan may select other suitable ways to use the control system 100, within the scope of the present disclosure.

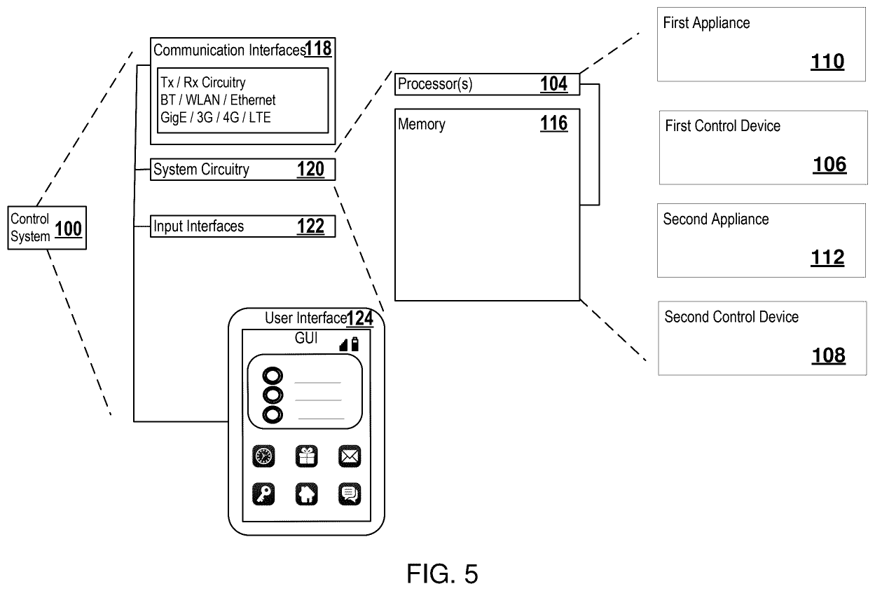

In certain circumstances, as shown in FIG. 5, the processor 104 may further include a communication interface 118, a system circuitry 120, and/or an input interface 122. The system circuitry 120 may include the processor 104 or multiple processors. The processor 104 or multiple processors may execute the steps to engage each of the first control device 106 coupled to the first appliance 110 and the second control device 108 coupled to the second appliance 112. Alternatively, or in addition, the system circuitry 120 may include memory 116.

The processor 104 may be in communication with the memory 116. In some examples, the processor 104 may also be in communication with additional elements, such as the communication interfaces 118, the input interfaces 122, and/or a user interface 124. Examples of the processor 104 may include a general processor, a central processing unit, logical CPUs/arrays, a microcontroller, a server, an application specific integrated circuit (ASIC), a digital signal processor, a field programmable gate array (FPGA), and/or a digital circuit, analog circuit, or some combination thereof.

The processor 104 may be one or more devices operable to execute logic. The logic may include computer executable instructions or computer code stored in the memory 116 or in other memory that when executed by the processor 104, cause the processor 104 to perform the operations of the first control device 106 and/or the second control device 108. The computer code may include instructions executable with the processor 104.

The memory 116 may be any device for storing and retrieving data or any combination thereof. The memory 116 may include non-volatile and/or volatile memory, such as a random-access memory (RAM), a read-only memory (ROM), an erasable programmable read-only memory (EPROM), or flash memory. Alternatively or in addition, the memory 116 may include an optical, magnetic (hard-drive), solid-state drive or any other form of data storage device. The memory 116 may be included in any component or sub-component of the system described herein.

The user interface 124 may include any interface for displaying graphical information. The system circuitry 120 and/or the communications interface(s) may communicate signals or commands to the user interface 124 that cause the user interface 124 to display graphical information. Alternatively or in addition, the user interface 124 may be remote to the system and the system circuitry 120 and/or communication interface(s) 118 may communicate instructions, such as HTML, to the user interface 124 to cause the user interface 124 to display, compile, and/or render information content. In some examples, the content displayed by the user interface 124 may be interactive or responsive to user input. For example, the user interface 124 may communicate signals, messages, and/or information back to the communications interface or system circuitry 120.

The system may be implemented in many different ways. In some examples, the system may be implemented with one or more logical components. For example, the logical components of the system may be hardware or a combination of hardware and software. In some examples, each logic component may include an application specific integrated circuit (ASIC), a Field Programmable Gate Array (FPGA), a digital logic circuit, an analog circuit, a combination of discrete circuits, gates, or any other type of hardware or combination thereof. Alternatively or in addition, each component may include memory hardware, such as a portion of the memory 116, for example, which comprises instructions executable with the processor 104 or other processor to implement one or more of the features of the logical components. When any one of the logical components includes the portion of the memory 116 that comprises instructions executable with the processor 104, the component may or may not include the processor 104. In some examples, each logical component may just be the portion of the memory 116 or other physical memory that comprises instructions executable with the processor 104, or other processor(s), to implement the features of the corresponding component without the component including any other hardware. Because each component includes at least some hardware even when the included hardware comprises software, each component may be interchangeably referred to as a hardware component.

Some features are shown stored in a computer readable storage medium (for example, as logic implemented as computer executable instructions or as data structures in memory). All or part of the system and its logic and data structures may be stored on, distributed across, or read from one or more types of computer readable storage media. Examples of the computer readable storage medium may include a hard disk, a flash drive, a cache, volatile memory, non-volatile memory, RAM, flash memory, or any other type of computer readable storage medium or storage media. The computer readable storage medium may include any type of non-transitory computer readable medium, such as a CD-ROM, a volatile memory, a non-volatile memory, ROM, RAM, or any other suitable storage device.

The processing capability of the system may be distributed among multiple entities, such as among multiple processors and memories, optionally including multiple distributed processing systems. Parameters, databases, and other data structures may be separately stored and managed, may be incorporated into a single memory or database, may be logically and physically organized in many different ways, and may implemented with different types of data structures such as linked lists, hash tables, or implicit storage mechanisms. Logic, such as programs or circuitry, may be combined or split among multiple programs, distributed across several memories and processors, and may be implemented in a library, such as a shared library (for example, a dynamic link library (DLL).

Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. Equivalent changes, modifications and variations of some embodiments, materials, compositions, and methods can be made within the scope of the present technology, with substantially similar results.

What is claimed is:

1. A control system configured to maintain a current draw of an electrical system below a predetermined amperage, the control system comprising:
an electrical meter configured to monitor the input information of the electrical system;
a processor communicatively coupled to the electrical meter, the processor includes an optimization algorithm;
wherein the optimization algorithm of the processor accepts the input information and outputs a control protocol to maintain the current draw below the predetermined amperage.

2. The control system of claim 1, wherein the control protocol includes one of selectively engaging and disengaging at least one of the first appliance and the second appliance.

3. The control system of claim 2, further comprising a first control device coupled to the first appliance and a second control device coupled to the second appliance; each of the first control device and the second control device are communicatively coupled to the processor.

4. The control system of claim 3, wherein at least one of the first control device and the second control device include a switch that the processor may selectively engage and disengage electrical current to at least one of the first appliance and the second appliance.

5. The control system of claim 4, wherein first control device and the second control device are smart plugs disposed between the electrical system and each of the first appliance and the second appliance, respectively.

6. The control system of claim 2, wherein at least one of the first appliance and the second appliance includes an application program interface that communicatively couples the at least one of the first appliance and the second appliance to the processor.

7. The control system of claim 1, wherein control protocol includes adjusting a setpoint of at least one of the first appliance and the second appliance.

8. The control system of claim 1, wherein the input information includes at least one of an electrical capacity of the electrical system, a performance limit of the electrical system, thermodynamic characteristics of the electrical system, and building/occupant usage characteristics.

9. The control system of claim 1, wherein the optimization algorithm predicts a future current draw and preemptively adjusts the control protocol to maintain the current draw below the predetermined amperage.

10. The control system of claim 1, wherein the processor is wirelessly coupled with each of the electrical meter, the first appliance, the second appliance.

11. A method of using a control system configured to maintain a current draw of an electrical system below a predetermined amperage, the method comprising the steps of:
obtaining the input information from the electrical system via an electrical meter;
transmitting the input information from the electrical meter to a processor;
performing an optimization algorithm via the processor;
outputting a control protocol; and
controlling the current draw of a first appliance and a second appliance below the predetermined amperage.

12. The method of claim 11, further comprising a step of monitoring real-time electrical draw from the electrical meter.

13. The method of claim 12, further comprising a step of performing the optimization algorithm as a predictive protocol by predicting a future current draw event and performing the optimization algorithm to preemptively adjust the control protocol to maintain the current draw below the predetermined amperage during the future current draw event.

14. The method of claim 13, further comprising a step of performing the optimization algorithm as a reactive protocol to output an update to the control protocol which may adjust the performance of at least one of the first device and the second device.

15. The method of claim 14, further comprising a step of engaging the reactive protocol for a predetermined period of time before reverting to the predictive protocol.

16. The method of claim 14, wherein the control protocol disengages at least one of the first appliance and the second appliance until the processor determines there is enough current capacity to engage the at least one of the first appliance and the second appliance without exceeding the predetermined amperage.

17. The method of claim 13, wherein the processor adjusts the control protocol to engage the first appliance and the second appliance during non-overlapping periods.

18. The method of claim 13, wherein processor adjusts the control protocol limit a setpoint of at least one of the first appliance and the second appliance to militate against exceeding the predetermined amperage.
